(19) United States
(12) Patent Application Publication
(10) Pub. No.: US 2019/0199281 A1
(43) Pub. Date: Jun. 27, 2019

(54) COMBINED SOLAR CELL MODULE

(71) Applicant: Industrial Technology Research Institute, Hsinchu (TW)

(72) Inventors: Jen-Chuan Chang, Taipei City (TW); Tung-Po Hsieh, Taipei City (TW); Chien-Rong Huang, New Taipei City (TW); Wei-Sheng Lin, Taoyuan City (TW); Chien-Hsing Lee, Hsinchu City (TW); Chin-Jen Chuang, Taoyuan City (TW)

(73) Assignee: Industrial Technology Research Institute, Hsinchu (TW)

(21) Appl. No.: 16/231,405

(22) Filed: Dec. 22, 2018

Related U.S. Application Data
(60) Provisional application No. 62/609,349, filed on Dec. 22, 2017.

(30) Foreign Application Priority Data
Oct. 19, 2018 (TW) 107136884

(51) Int. Cl. H02S 40/36; H01L 31/05; H01R 13/62

(52) U.S. Cl. CPC H02S 40/36; H01R 13/6205; H01L 31/0504

(57) ABSTRACT

A combined solar cell module includes a solar cell module, an end connection device, and an output connection device. The solar cell module includes first and second connection portions on opposite sides of a substrate, and connection lines which connect solar cells to the first and second connection portions. The first connection portion has a first holding space. The second connection portion has a second holding space corresponding to the first holding space in an up-and-down manner. First and second connection parts are within the first and second holding spaces respectively. At least one of the first and second connection parts is a magnetic material, and another one is a magnetic material or a magnetically attractable material. The end connection device and the first connection portion are detachable and connectable. The output connection device and the second connection portion are detachable and connectable, for outputting current generated by solar cells.

### CROSS-REFERENCE TO RELATED APPLICATION

This application claims the priority benefits of U.S. provisional application Ser. No. 62/609,349, filed on Dec. 22, 2017, and Taiwan application serial no. 107136884, filed on Oct. 19, 2018. The entirety of each of the above-mentioned patent applications is hereby incorporated by reference herein and made a part of this specification.

### TECHNICAL FIELD

The disclosure relates to a combined solar cell module.

### BACKGROUND

Under the theme of globalization, using emerging energy sources and energy saving green technologies have become the focus of attention. Among these energy sources, solar energy is a clean, pollution-free and inexhaustible energy. Therefore, a solar cell module that can directly convert solar energy into electrical energy has become the focus of current development in utilizing solar energy.

In general, multiple solar cell modules are connected together in order to provide greater output power. However, in order to make the combined solar cell modules firm and stable, a complicated and relatively difficult assembly method is required, so it is relatively uneasy to disassemble such solar cell modules.

However, if quick disassembly of the solar cell modules is required, the connection strength between the solar cell modules is usually not high enough, and thus, such solar cell modules are easily disconnected.

### SUMMARY

The disclosure provides a combined solar cell module, which can be quickly combined to achieve the effects of easy installation, easy disassembly, stable connection, and uneasy falling off horizontally.

The combined solar cell module of the disclosure includes at least one solar cell module, an end connection device and an output connection device. The solar cell module includes a substrate, a plurality of solar cells, a first connection portion, a second connection portion, a plurality of first connection parts, a plurality of second connection parts and a plurality of first connection lines. The substrate has a first opposite side and a second opposite side opposite to each other. The solar cells are located on the substrate. The first connection portion is disposed on the first opposite side of the substrate, and has a first holding space therein. The first holding space is recessed. The second connection portion is disposed on the second opposite side of the substrate, and has a second holding space therein. The first connection parts are respectively disposed in the first holding space. The second connection parts respectively disposed in the second holding space. A shape of the second holding space disposed with the second connection parts matches a shape of the first holding space disposed with the first connection parts in an up-and-down manner, so that exposed surfaces of the second connection parts correspond to exposed surfaces of the first connection parts in an up-and-down manner, and at least one of the first connection parts and the second connection parts is a magnetic material, and another one of the first connection parts and the second connection parts is a magnetic material or a magnetically attractable material. The first connection lines connect the solar cells to the first connection parts and connect the solar cells to the second connection parts, respectively, so as to transmit current generated by the solar cells to the first connection parts and the second connection parts via first connection lines. The end connection device is detachable and connectable to the first connection portion, and configured to electrically connect the first connection parts. The output connection device is detachable and connectable to the second connection portion, and configured to electrically connect the second connection parts and output the current generated by the solar cells.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a top exploded view of a combined solar cell module in accordance with a first embodiment of the present disclosure.

FIG. 1B is a schematic cross-sectional view taken along line B-B′ of FIG. 1A.

FIG. 2A is a top view of a combined solar cell module in accordance with a second embodiment of the present disclosure.

FIG. 2B is a schematic cross-sectional view taken along line B-B′ of FIG. 2A.

FIG. 3 is a top plan view of a combined solar cell module in accordance with a third embodiment of the present disclosure.

FIG. 4 is a top plan view of an output connection device in accordance with a third embodiment of the present disclosure.

FIG. 5 is a schematic cross-sectional view taken along line V-V′ of FIG. 3.

FIG. 6 is a schematic cross-sectional view of another output connection device in accordance with the third embodiment.

FIG. 7A is a top exploded view of a combined solar cell module in accordance with a fourth embodiment of the present disclosure.

FIG. 7B is a schematic cross-sectional view taken along line B-B′ of FIG. 6A.

### DETAILED DESCRIPTION OF DISCLOSED EMBODIMENTS

The disclosure is described below with reference to the drawings, but the disclosure may be implemented in many different forms and is not limited to the description of the embodiments. In the drawings, for clarity, the dimensions and relative dimensions of the various layers and regions may not be drawn to scale.

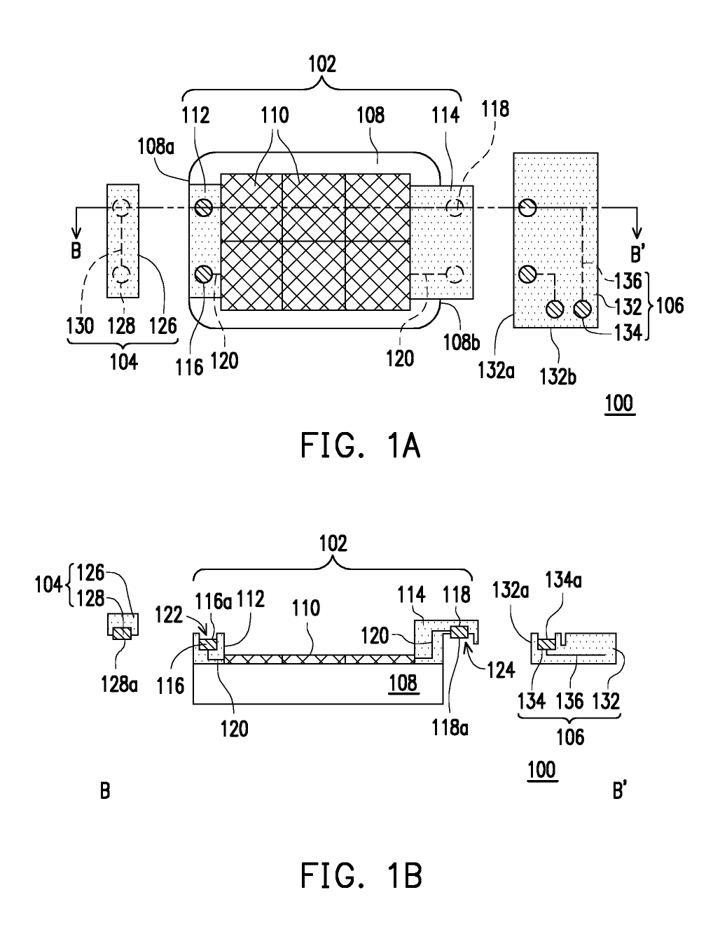

FIG. 1A is a top exploded view of a combined solar cell module in accordance with a first embodiment of the present disclosure. FIG. 1B is a schematic cross-sectional view taken along line B-B′ of FIG. 1A.

Referring to FIG. 1A and FIG. 1B simultaneously, the combined solar cell module 100 of the first embodiment includes a solar cell module 102, an end connection device 104, and an output connection device 106. In the first embodiment, the number of the solar cell module 102 is one, but the present disclosure is not limited thereto. The number of the solar cell module 102 may be plural, and may be connected in series, in parallel, or in mixed series-parallel relationship, for expanding and achieving the effect of the solar cell module 102. Each solar cell module 102 includes a substrate 108, a plurality of solar cells 110 on the substrate 108, a first connection portion 112, a second connection portion 114, a plurality of first connection parts 116, a plurality of second connection parts 118, and a plurality of first connection lines 120. The first connection lines 120 connect the solar cells 110 to the first connection parts 116, and connect the solar cells 110 to the second connection parts 118, respectively. Specifically, multiple solar cells 110 can be connected to the same first connection part 116 by the same first connection line 120, and connected to the same second connection part 118 by the same first connection line 120, so as to form a single solar cell group. However, this single solar cell group is not connected to another first connection line 120, another first connection part 116 and another second connection part 118. That is, in the same solar cell group, multiple solar cells 110 are connected to the same first connection line 120, the same first connection part 116 and the same second connection part 118, but between different solar cells groups, their respective first connection lines 120, the first connection parts 116 and the second connection parts 118 are not connected. The substrate 108 has a first opposite side 108a and a second opposite side 108b which are disposed opposite to each other, the first connection portion 112 is disposed on the first opposite side 108a of the substrate 108 and has a first holding space 122 therein. The first holding space 122 is recessed. Besides, in addition to the rectangular shape illustrated in FIG. 1A, the shape of the first connection portion 112 may also be a square shape, a rounded rectangle shape, a polygonal shape, a circular shape, an elliptical shape, a T-shape, or the like. The second connection portion 114 is disposed on the second opposite side 108b of the substrate 108 and has a second holding space 124 therein. Besides, in addition to the rectangular shape illustrated in FIG. 1A, the shape of the second connection portion 114 may also be a square shape, a rounded rectangle shape, a polygonal shape, a circular shape, an elliptical shape, a T-shape, or the like. The first connection parts 116 are respectively disposed in the first holding space 122, and the second connection parts 118 are respectively disposed in the second holding space 124. It is noted that, the first connection parts 116 do not occupy the entire first holding space 122, the second connection parts 118 do not occupy the entire second holding space 124, and the shape of the second holding space 124 disposed with the second connection parts 118 matches the shape of the first holding space 122 disposed with the first connection part 116 in an up-and-down manner, so that the exposed surfaces 118a of the second connection parts 118 correspond to the exposed surfaces 116a of the first connection parts 116 in an up-and-down manner. In this embodiment, the second connection portion 114 and the first connection portion 112 are both disposed on the same surface of the substrate 108, the first connection portion 112 is a convex portion, the second connection portion 114 is a cover member having a corresponding shape covering the first connection portion 112, and the second connection parts 118 are located on the top inner surface of the cover member. Therefore, in the first embodiment, the connection strength between the first connection portion 112 and the second connection portion 114 is high, and lateral displacement or slip does not occur. In another embodiment, the shape of the first connection portion 112 and the shape of the second connection portion 114 may also be exchanged; that is, the first connection portion 112 may be a cover member, and the second connection portion 114 may be a convex portion, as long as the structures of the first and second connection portions 112 and 114 correspond to the structures of the end connection device 104 and the output connection device 106. The structures are not limited to those listed.

The first connection lines 120 connect the solar cells 110 to the first connection parts 116, and connect the solar cells 110 to the second connection parts 118, so as to transmit the current generated by the solar cells 110 to the first connection parts 116 and the second connection parts 118 via the first connection lines 120, respectively. Therefore, the first connection parts 116 and the second connection parts 118 can serve as a connection device and a current output terminal at the same time. The first connection parts 116 and the second connection parts 118 have a resistivity of less than 10⁻² ohm-cm, for facilitating the current transmission. For example, the first connection parts 116 and the second connection parts 118 have a resistivity of less than 10⁻⁴ ohm-cm. In FIG. 1B, the first connection lines 120 are in contact with the solar cells 110 in a schematic manner, and it is understood that, the first connection lines 120 may be connected to bus lines (not shown) of the solar cells 110, and each first connection part 116 and/or each second connection part 118 may be connected to one or more first connection lines 120. For example, each of the first connection lines 120 can be designed to have two wires or four wires, for providing voltage and current transmission functions, as well as for providing other module application functions.

In an embodiment, the first connection parts 116 and the second connection parts 118 are both magnetic materials (such as magnets), and the magnetic poles of the first connection parts 116 are different from the magnetic poles of the second connection parts 118. Alternatively, respective first connection parts 116 have different magnetic poles and respective second connection parts 118 have different magnetic poles. For example, the magnetic materials on the same side (i.e., the same opposite side) of the solar cell module 102 may have different magnetic poles (N, S or S, N), and the magnetic materials on another side of the solar cell module 102 may have corresponding magnetic poles (S, N or N, S). Alternatively, the magnetic materials on the same side of the solar cell module 102 may have the same magnetic pole (N, N or S, S), and the magnetic materials on another side of the solar cell module 102 may have the corresponding magnetic pole (S, S or N, N). In another embodiment, one of the first connection parts 116 and the second connection parts 118 is a magnetic material (N, S or S, N or S, S or N, N), and another one of the first connection parts 116 and the second connection parts 118 is a magnetically attractable material (e.g., a ferromagnetic material, such as iron, nickel, cobalt or a metal material), and the magnetic materials may have the same or different magnetic poles. The magnetic material can be one of ferrite, neodymium iron boron, alnico alloy, iron chrome cobalt alloy, samarium cobalt, samarium iron nitrogen, and the like; alternatively, a conductive layer (not shown) is used to cover a typical magnetic material, serving as the first connection part 116 and/or the second connection part 118.

In the first embodiment, a positive electrode and a negative electrode is disposed on the same side (i.e., the same opposite side) of the solar cell module 102, and the corresponding negative electrode and the corresponding positive electrode are disposed on another side of the solar cell module 102. That is, the first connection parts 116 on the first opposite side 108a are configured to have a positive electrode and a negative electrode, and the second connection parts 118 on the second opposite side 108b are configured to have a negative electrode and a positive electrode. In this way, respective solar cell groups can be operated in series. However, the present disclosure is not limited thereto, and any line capable of outputting the current generated by the solar cells 110 can be applied to the solar cell module 102 of the present disclosure.

Continue referring to FIG. 1A and FIG. 1B, the end connection device 104 is detachable and connectable to the first connection portion 112, and configured to electrically connect the first connection parts 116, and the output connection device 106 is detachable and connectable to the second connection portion 114, and configured to electrically connect the second connection parts 118, and thus, an output loop is generated to output the current generated by the solar cells 110. The end connection device 104 of the first embodiment includes an end connection portion 126, a plurality of end connection parts 128, and a second connection line 130. The end connection parts 128 are disposed on the end connection portion 126, and the exposed surfaces 128a of the end connection parts 128 correspond to the exposed surfaces 116a of the first connection parts 116 in an up-and-down manner, wherein the number of end connection parts 128 may be the same as the number of first connection parts 116. The second connection lines 130 connect these end connection parts 128, so that the end connection parts 128 are connected in series. In the present embodiment, at least one of the first connection parts 116 and the end connection parts 128 is a magnetic material, and another one is a magnetic material or a magnetically attractable material. That is, when the first connection parts 116 are magnetic materials, the end connection parts 128 are magnetic materials or magnetically attractable materials; when the first connection parts 116 are magnetically attractable materials, the end connection parts 128 are magnetic materials, and vice versa. In an embodiment, the end connection parts 128 have a resistivity of less than 10⁻² ohm-cm, for example.

The output connection device 106 of the first embodiment may include an output connection portion 132, a plurality of output connection parts 134, and a plurality of third connection lines 136 that connect the output connection parts 134. The output connection parts 134 are disposed on a first adjacent side 132a and a second adjacent side 132b adjacent to the output connection portion 132. However, the present disclosure is not limited thereto. The number and position of the output connection parts 134 can be adjusted as needed, as long as the exposed surface 134a of the output connection parts 134 correspond to the exposed surfaces 118a of the second connection parts 118 in an up-and-down manner, and the effect of outputting the current generated by the solar cells 110 can be achieved. In the present embodiment, at least one of the second connection parts 118 and the output connection parts 134 is a magnetic material, and another one is a magnetic material or a magnetically attractable material. That is, when the second connection parts 118 are magnetic materials, the output connection parts 134 are magnetic materials or magnetically attractable materials; when the second connection parts 118 are magnetically attractable materials, the output connection parts 134 are magnetic materials, and vice versa. In an embodiment, the connection output parts 134 have a resistivity of less than 10⁻² ohm-cm, for example. The third connection lines 136 are connected to the output connection parts 134. Specifically, the third connection lines 136 respectively connect portions of the output connection parts 134 corresponding to the second connection parts 118 and portions of the output connection parts 134 not corresponding to the second connection parts 118.

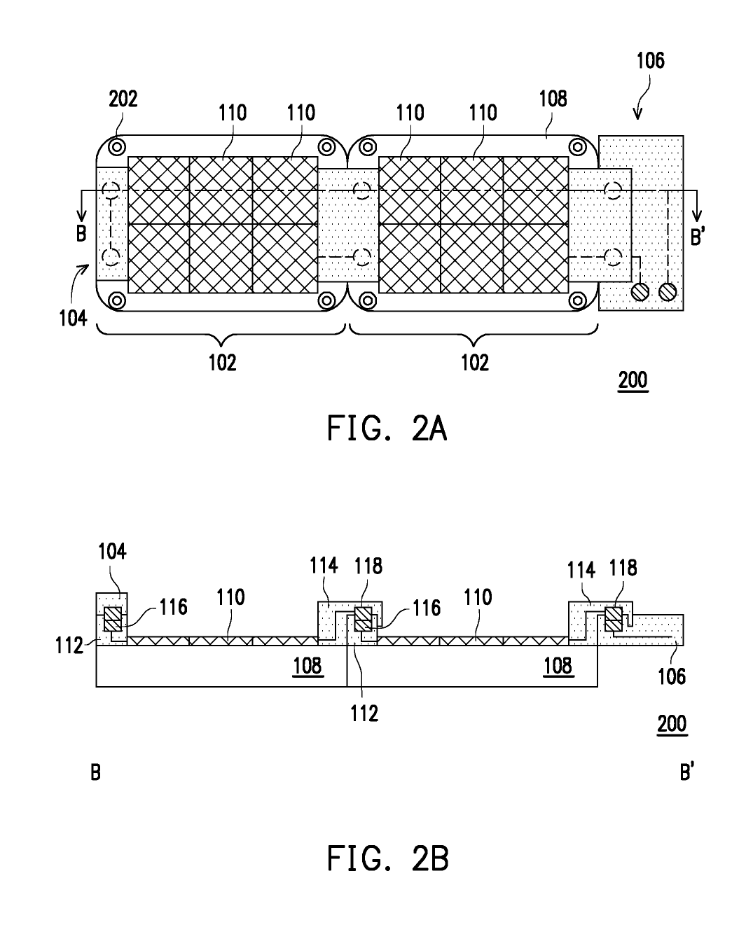

FIG. 2A is a top view of a combined solar cell module in accordance with a second embodiment of the present disclosure. FIG. 2B is a schematic cross-sectional view taken along line B-B′ of FIG. 2A. The same reference numerals in the first embodiment are used to denote the same or similar components, so the same or similar components may also be referred to the first embodiment, and the details are not iterated herein.

Referring to FIG. 2A and FIG. 2B, the combined solar cell module 200 is composed of two solar cell modules 102, an end connection device 104, and an output connection device 106. In the second embodiment, although only two solar cell modules 102 are shown, it is understood that, according to the requirements, the number of solar cell modules 102 can be increased to more than two, and a boost circuit or a typical wiring can be added to boost the voltage. When the solar cell modules 102 are assembled to each other, the first connection portion 112 of one solar cell module 102 is connected to the second connection portion 114 of the other solar cell module 102, and the second connection parts 118 and the first connection parts 116 are connected by magnetic attraction in an up-and-down manner, so as to transmit the current. At the same time, the end connection device 104 installed at the end of the combined solar cell module 200 can be electrically connected to the first connection parts 116 of the first connection portion 112 of one solar cell module 102, and the output connection device 106 installed at the output of the combined solar cell module 200 can be electrically connected to the second connection parts 118 of the second connection portion 114 of the other solar cell module 102, so as to output the current generated by the solar cells 110. In addition, four corners of the solar cell modules 102 can also be provided with fixing members 202, such as grommets, eyelets, collars, buckles, etc., in order to fix the combined solar cell module 200 to other facilities (such as buildings, vehicles, walls, floors, etc.) after completing the combination of the solar cell module 102, the end connection device 104 and the output connection device 106.

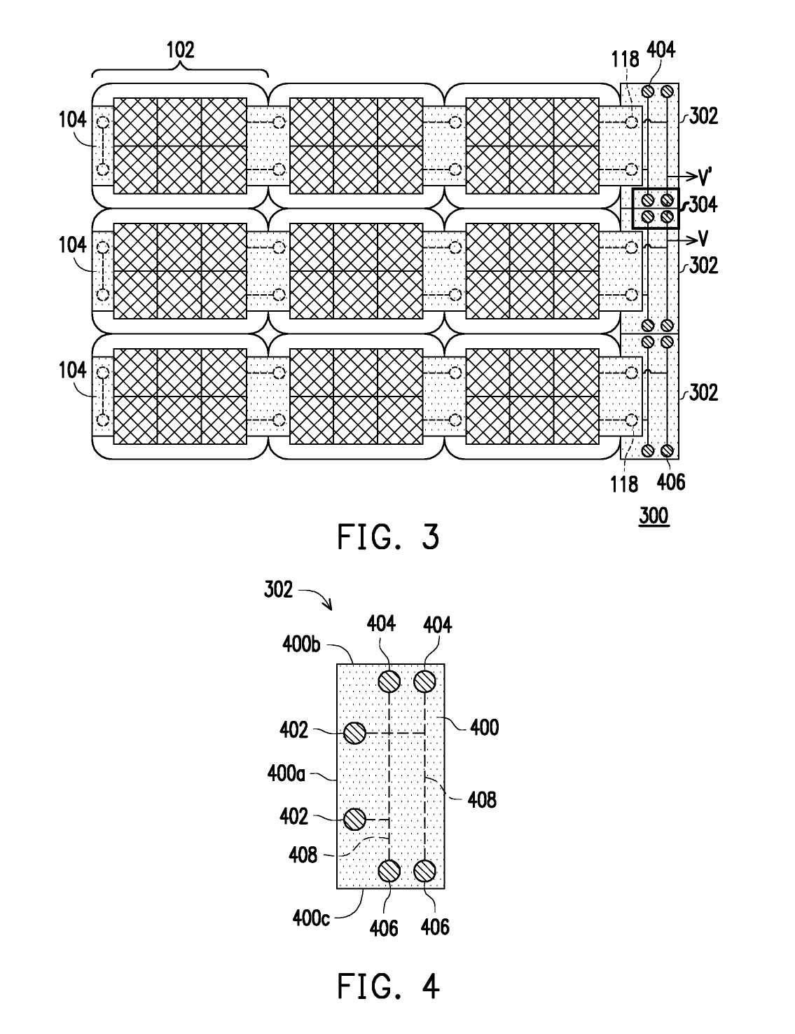

FIG. 3 is a top plan view of a combined solar cell module in accordance with a third embodiment of the present disclosure. The same reference numerals in the first embodiment are used to denote the same or similar components, so the same or similar components may also be referred to the first embodiment, and the details are not iterated herein.

Referring to FIG. 3, the combined solar cell module 300 of the third embodiment includes nine solar cell modules 102, three end connection devices 104, and three output connection devices 302. Every three solar cell modules 102 are coupled together and connected in series by an end connection device 104 and then connected to an output connection device 302. Since the output connection devices 302 can be connected to each other, a set of three solar cell modules 102 connected in series can form a parallel circuit with other two sets of three solar cell modules 102 connected in series by the output connection devices 302. In addition, the output connection devices 302 can be provided with a display (not shown) to display the voltage and current; or can be connected to the required output terminals, so as to increase the flexibility of use.

FIG. 4 is a top plan view of the output connection device 302 in the third embodiment.

In FIG. 4, the output connection device 302 includes an output connection portion 400, a plurality of first output connection parts 402, a plurality of second output connection parts 404, a plurality of third output connection parts 406, and a plurality of third connection lines 408. The first output connection parts 402 are disposed on one side 400a of the output connection portion 400, and the exposed surfaces of the first output connection parts 402 correspond to the exposed surfaces of the second connection parts (118 of FIG. 3) in an up-and-down manner. In the output connection device 302 of the third embodiment, the second and third output connection parts 404 and 406 connected to the same first output connection part 402 are of the same polarity (positive or negative) for respectively connecting the positive and negative electrodes of the solar cell module 102, for serving as connection output terminals or for using as a parallel expansion.

Moreover, at least one of the second connection parts (118 of FIG. 3) and the first output connection parts 402 is a magnetic material, and another one is a magnetic material or a magnetically attractable material. That is, when the second connection parts 118 are magnetic materials, the first output connection parts 402 are magnetic materials or a magnetically attractable materials; when second connection parts 118 are magnetically attractable materials, the first output connection parts 402 are magnetic materials, and vice versa. The second output connection parts 404 are disposed on a first adjacent side 400b adjacent to the one side 400a, and the third output connection parts 406 are disposed on a second adjacent side 400c adjacent to the one side 400a. The second output connection parts 404 of one output connection device 302 and the third output connection parts 406 of another output connection device 302 are detachable and connectable. Each of the third connection lines 408 connects one of the first output connection parts 402, and connects the second output connection part 404 and the third output connection part 406 that connect the same first output connection part 402.

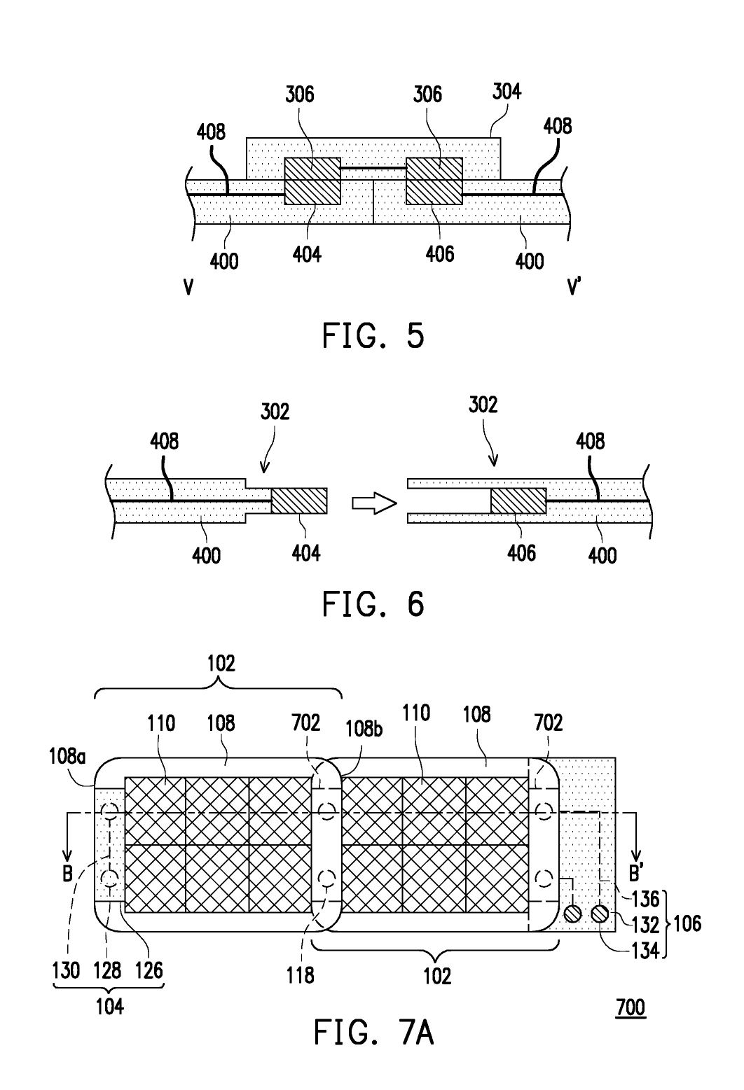

Referring again to FIG. 3, if the second output connection parts 404 and the third output connection parts 406 between two output connection devices 302 are connected by magnetic attraction, a connection device 304 may be added, as shown in FIG. 5. FIG. 5 is a schematic cross-sectional view taken along line V-V′ of FIG. 3, showing that the connection device 304 has connection parts 306 electrically connected to each other. When the second output connection parts 404 and the third output connection parts 406 are magnetic materials, the connection parts 306 are magnetic materials or magnetically attractable materials; when the second output connection parts 404 and the third output connection parts 406 are magnetically attractable materials, the connection parts 306 are magnetic materials, and vice versa.

In addition, the second output connection parts 404 and the third output connection parts 406 may also adopt other connection manners, such as the connection manner between the first connection portion 112 and the second connection portion 114 of the first embodiment, so that one of the second output connection parts 404 and the third output connection parts 406 is a convex portion and another one is a cover member; or the connection manner with an engaged structure as shown in FIG. 6.

In FIG. 6, the second output connection parts 404 are located in the convex portion of the output connection portion 400, and the third output connection parts 406 are located in the concave portion of the output connection portion 400. The shapes of the convex portion and the concave portion of the output connection portion 400 can be matched to each other, so that the second output connection parts 404 and the third output connection parts 406 between two output connection devices 302 are simultaneously connected and current-transmitted in the form of a male-female joint, and an additional connection part is not required.

In another embodiment, the output connection device 302 may also be a single entity (e.g., wires and connectors, etc.) configured to provide an electrical parallel connection for all of the solar cell modules 102 connected in series.

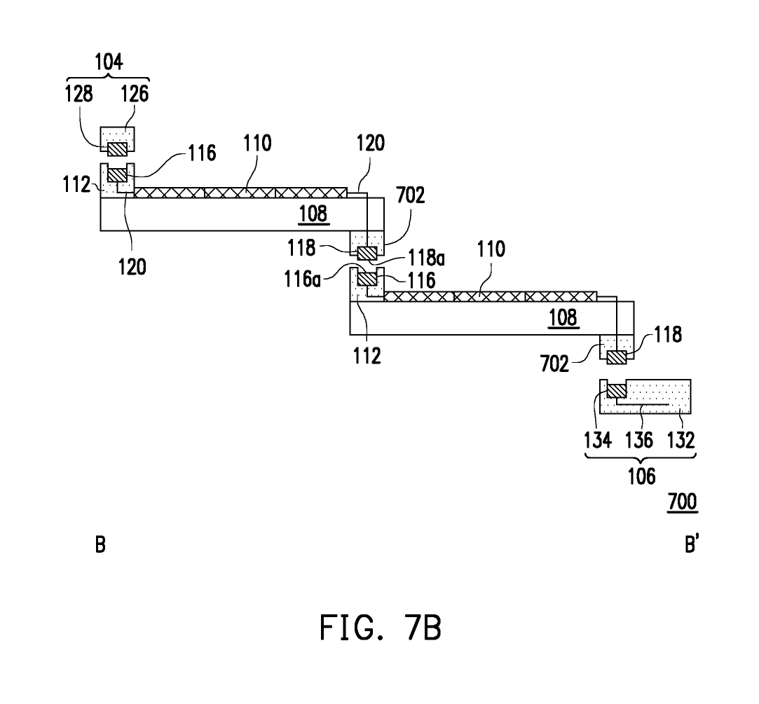

FIG. 7A is a top exploded view of a combined solar cell module in accordance with a fourth embodiment of the present disclosure. FIG. 7B is a schematic cross-sectional view taken along line B-B′ of FIG. 7A. The same reference numerals in the first embodiment are used to denote the same or similar components, so the same or similar components may also be referred to the first embodiment, and the details are not iterated herein.

Referring to FIG. 7A and FIG. 7B simultaneously, the combined solar cell module 700 of the fourth embodiment is similar to that of the first embodiment. It is noted that, the second connection portion 702 and the first connection portion 112 are disposed on different surfaces of the substrate 108, the second connection parts 118 are located on the second connection portion 702 and are slightly convex, so that the exposed surfaces 118a of the second connection parts 118 correspond to the exposed surfaces 116a of the first connection parts 116 in an up-and-down manner.

After the solar cell modules 102 are assembled to each other, the first connection portion 112 of the solar cell module 102 is connected to the second connection portion 702 of another one solar cell module 102, and the second connection parts 118 and the first connection parts 116 are connected by magnetic attraction such that the second connection parts 118 correspond to the first connection parts 116 in an up-and-down manner for electrical connection and current transmission. In addition, in the fourth embodiment, the end connection device 104 and the first connection portion 112 are detachable and connectable to electrically connect to the first connection parts 116; the output connection device 106 and the second connection portion 702 are detachable and connectable to electrically connect the second connection parts 118 and output the current generated by the solar cells 110. Moreover, the shape of the output connection device 106 may vary depending on the shape of the second connection portion 702, and is not limited to the drawing. Other components of the combined solar cell module 700 can be referred to those described in the first embodiment.

The following examples are provided to verify the effects of the present disclosure, but the present disclosure is not limited to the following.

<Experimental Example>

Two solar cell modules as shown in FIG. 1A are manufactured, which are module A and module B. Their electrical characteristics are then measured respectively, as shown in Table 1 below.

The end connection device and the output connection device as shown in FIG. 1A are manufactured. The module A and the module B are connected in series by magnetic attraction, and the end connection device and the output connection device are assembled to obtain the combined solar cell module as shown in FIG. 2A. The electrical characteristics after the series connection are measured, as shown in Table 1 below.

TABLE 1

| | Area | V_{OC} | Vₘₐₓ | I_{SC} | Iₘₐₓ | F.F. | Pₘₐₓ |
|---|---|---|---|---|---|---|---|
| module | (cm²) | (V) | (V) | (A) | (A) | (%) | (W) |
| A | 720 | 2.87 | 1.92 | 3.44 | 2.36 | 45.91 | 4.52 |
| B | 720 | 2.89 | 1.93 | 3.48 | 2.41 | 49.09 | 4.64 |
| A + B | 1440 | 5.75 | 3.62 | 3.4 | 2.34 | 43.25 | 8.45 |
| (series connection) | | | | | | | |

As seen from Table 1, the power of module A and module B before the series connection is about 4.5 W to 4.6 W, and the actual power of the combined solar cell module after serial connection is about 8.45 W. Thus, such magnetic connection is workable for power generation and operation.

In summary, the combined solar cell modules of the present disclosure are connected by magnetic attraction, and the connected device have corresponding shapes and can provide the functions of electrical connection and current transmission, and therefore, respective solar cell modules can be quickly combined together, and achieve the effects of easy installation, easy disassembly, stable connection, and uneasy falling off horizontally. The end connection device and output connection device can be connected, in series or in parallel, to the modules by magnetic attraction, in order to facilitate the rapid assembly and expansion of the solar cell modules. As the result, the combined solar cell module can be adjusted according to the desired voltage or current, and can be easily stored and assembled.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A combined solar cell module, comprising:
at least one solar cell module, comprising:
a substrate having a first opposite side and a second opposite side opposite to each other;
a plurality of solar cells, located on the substrate;
a first connection portion, disposed on the first opposite side of the substrate, and having a first holding space therein;
a second connection portion, disposed on the second opposite side of the substrate, and having a second holding space therein;
a plurality of first connection parts, respectively disposed in the first holding space;
a plurality of second connection parts, respectively disposed in the second holding space, wherein a shape of the second holding space disposed with the plurality of second connection parts matches a shape of the first holding space disposed with the plurality of first connection parts in an up-and-down manner, so that exposed surfaces of the plurality of second connection parts correspond to exposed surfaces of the plurality of first connection parts in an up-and-down manner, and at least one of the plurality of first connection parts and the plurality of second connection parts is a magnetic material, and another one of the plurality of first connection parts and the plurality of second connection parts is a magnetic material or a magnetically attractable material; and
a plurality of first connection lines, connecting the plurality of solar cells to the plurality of first connection parts and connecting the plurality of solar cells to the plurality of second connection parts, respectively, so as to transmit current generated by the plurality of solar cells to the plurality of first connection parts and the plurality of second connection parts via the plurality of first connection lines;
an end connection device, being detachable and connectable to the first connection portion, and configured to electrically connect the plurality of first connection parts; and
an output connection device, being detachable and connectable to the second connection portion, and configured to electrically connect the plurality of second connection parts and output the current generated by the plurality of solar cells.

2. The combined solar cell module of claim 1, wherein the second connection portion and the first connection portion are disposed on the same surface of the substrate.

3. The combined solar cell module of claim 2, wherein the second connection portion is a cover member, the cover member has a shape covering the first connection portion, and the plurality of second connection parts are located on a top inner surface of the cover member.

4. The combined solar cell module of claim 1, wherein the second connection portion and the first connection portion are disposed on different surfaces of the substrate.

5. The combined solar cell module of claim 1, wherein the plurality of first connection parts and the plurality of second connection parts are both magnetic materials.

6. The combined solar cell module of claim 1, wherein the plurality of first connection parts are magnetic materials and the plurality of second connection parts are magnetically attractable materials; or the plurality of second connection parts are magnetic materials and the plurality of first connection parts are magnetically attractable materials.

7. The combined solar cell module of claim 1, wherein the end connection device comprises:
an end connection portion;
a plurality of end connection parts, disposed on the end connection portion, wherein exposed surfaces of the plurality of end connection parts correspond to the exposed surfaces of the plurality of first connection parts in an up-and-down manner, and wherein at least one of the plurality of first connection parts and the plurality of end connection parts is a magnetic material, and another one of the plurality of first connection parts and the plurality of end connection parts is a magnetic material or a magnetically attractable material; and
at least one second connection line, connecting the plurality of end connection parts.

8. The combined solar cell module of claim 7, wherein a number of the plurality of end connection parts is the same as a number of the plurality of first connection parts.

9. The combined solar cell module of claim 7, wherein the plurality of end connection parts have a resistivity of less than 10⁻² ohm-cm.

10. The combined solar cell module of claim 1, wherein the output connection device comprises:
an output connection portion;
a plurality of output connection parts, disposed on the output connection portion, wherein exposed surfaces of the plurality of output connection parts correspond to the surfaces of the plurality of second connection parts in an up-and-down manner, and wherein at least one of the plurality of second connection parts and the plurality of output connection parts is a magnetic material, and another one of the plurality of second connection parts and the plurality of output connection parts is a magnetic material or a magnetically attractable material; and
a plurality of third connection lines, connecting the plurality of output connection parts.

11. The combined solar cell module of claim 10, wherein the plurality of third connection lines respectively connect portions of the plurality of output connection parts corresponding to the plurality of second connection parts and portions of the plurality of output connection parts not corresponding to the plurality of second connection parts.

12. The combined solar cell module of claim 10, wherein the plurality of output connection parts are respectively disposed on a first adjacent side and a second adjacent side adjacent to the output connection portion.

13. The combined solar cell module of claim 10, wherein the plurality of output connection parts have a resistivity of less than 10⁻² ohm-cm.

14. The combined solar cell module of claim 1, wherein the output connection device comprises:
an output connection portion;
a plurality of first output connection parts, disposed on one side of the output connection portion, wherein exposed surfaces of the plurality of first output connection parts correspond to the exposed surfaces of the plurality of second connection parts in an up-and-down manner, and wherein at least one of the plurality of second connection parts and the plurality of first output connection parts is a magnetic material, and another one of the plurality of second connection parts and the plurality of first output connection parts is a magnetic material or a magnetically attractable material;
a plurality of second output connection parts, disposed on a first adjacent side adjacent to the one side;
a plurality of third output connection parts, disposed on a second adjacent side adjacent to the one side, wherein the plurality of second output connection parts and the plurality of third output connection parts are detachable and connectable; and
a plurality of third connection lines, wherein each of the plurality of third connection lines connects one of the plurality of first output connection parts, and connects the plurality of second output connection part and the plurality of third output connection part that connect the same one of the plurality of first output connection parts.

15. The combined solar cell module of claim 14, wherein the plurality of second output connection parts are located on a convex portion of the output connection portion, the third plurality of output connection parts are located on a concave portion of the output connection portion, and a shape of the convex portion of the output connection portion and a shape of the concave portion of the output connection portion match each other.

16. The combined solar cell module of claim 1, wherein the plurality of first connection parts and the plurality of second connection parts have a resistivity of less than 10⁻² ohm-cm.

17. The combined solar cell module of claim 1, wherein the magnetic material comprises one of ferrite, neodymium iron boron, alnico alloy, iron chrome cobalt alloy, samarium cobalt, and samarium iron nitrogen.

18. The combined solar cell module of claim 1, wherein when the plurality of first connection parts are magnetic materials, the plurality of first connection parts further comprise a conductive layer covering the magnetic materials.

19. The combined solar cell module of claim 1, wherein when the plurality of second connection parts are magnetic materials, the plurality of second connection parts further comprise a conductive layer covering the magnetic materials.

20. The combined solar cell module of claim 1, wherein the at least one solar cell module is a plurality of solar cell modules, and the first connection portion of one of the at least one solar cell module connects the second connection portion of another one of the at least one solar cell module.
